(19) United States
(12) Patent Application Publication
(10) Pub. No.: US 2011/0133327 A1
(43) Pub. Date: Jun. 9, 2011

(54) SEMICONDUCTOR PACKAGE OF METAL POST SOLDER-CHIP CONNECTION

(76) Inventors: Hung-Hsin Hsu, Hukou Shiang (TW); Chin-Ming Hsu, Hukou Shiang (TW); Jui-Ching Hsu, Hukou Shiang (TW)

(21) Appl. No.: 12/634,330

(22) Filed: Dec. 9, 2009

(51) Int. Cl. H01L 23/498

(52) U.S. Cl. 257/692; 257/E23.06

(57) ABSTRACT

A semiconductor package with MPS-C2 configuration is revealed, primarily comprising a substrate and a chip. A plurality of leads covered by a solder mask having a rectangular slot disposed on the top surface of the substrate to expose parts of the leads. A plurality of metal pillars are disposed on the active surface of the chip. A patterned plating layer is partially formed on the exposed portions of the leads located inside the slot to form a plurality of plating-defined fingers. Therefore, the soldering area of the solder on the leads can be constrained without exceeding the patterned plating layer to avoid issue of excessive solder ability.

### FIELD OF THE INVENTION

The present invention relates to a semiconductor device, and more particularly to a semiconductor package with metal post solder-chip connections (MPS-C2) configuration.

### BACKGROUND OF THE INVENTION

In the conventional flip-chip bonding technology, a plurality of solder bumps with 20 um diameters are disposed on the active surface of a chip first, then the bumped chip is flipped and reflowed to become solder balls to electrically and mechanically join to the corresponding bonding pads of a substrate to complete a flip chip assembly. Since flip-chip bonding technology is widely implemented in semiconductor packages with high density I/O to provide shorter electrical interconnections between chips and substrates leading to better signal quality for high frequency applications. However, during reflowing processes, the spacing between solder bumps is automatically shortened due to the shape changing of solder bumps into solder balls. In order to avoid electrical short caused by bridging between two adjacent solder balls, the solder bump pitch have to increase to more than 50 um, therefore, the solder bumps can not directly be disposed on the bonding pads of a chip where redistribution layer (RDL) is needed to rearrange locations of the solder bumps into an array to increase the spacing between solder bumps. Therefore, when the development of fine-pitch solder bumps for most advanced semiconductor packaging technology continues, the conventional flip-chip bonding technology with solder bumps can not further be implemented in solder bump spacing under 50 um with solder bump diameters/lengths under 20 um.

Therefore, an advanced technology has been developed by IBM to implement metal pillars to replace conventional solder bumps where little solder paste is used to join metal pillars to the connecting pads of substrates. Since the shapes of the metal pillars are not be changed during reflowing processes, the metal pillar pitch can further be designedly shortened to match with the bonding pad pitch of a chip below 50 um such as 30 um to achieve even higher density I/O design. This conventional technology is called Metal Post Solder-Chip Connection (MPS-C2) which is revealed in U.S. Pat. No. 6,229,220 B1 where the metal pillars are made of high temperature materials and the connecting pads of the substrates are NSMD (Non-solder mask defined) so that the soldering area of the low temperature solder on the metal pillars jointed to the connecting pads of the substrate is completely decided by the dimension of the connecting pads. However, since NSMD connecting pads are connected with exposed traces or leads, the solder contamination issues due to solder expansion will be encountered, i.e., the issue of excessive solder ability. Furthermore, since the adhesion of NSMD connecting pads on substrate core is poor so that the NSMD connecting pads easily peel from the top surface of the substrate when experienced the stresses from the solder of the metal pillars.

In order to resolve the issue of excessive solder ability and the peeling of connecting pads from the substrate, MPS-C2 structure had been further improved. As shown in FIG. 1, a conventional MPS-C2 package 100 primarily comprises a substrate 110, a chip 120, and a semiconductor package body 150 where the top surface 111 of the substrate 110 is shown in FIG. 2. As shown in FIG. 1 and FIG. 2, a plurality of solder mask defined (SMD) pads 112 are disposed on the top surface 111 of the substrate 110, i.e., a solder mask 113 covered the peripheries of the SMD pads 112 and the traces connected to the SMD pads 112 not shown in the figure, i.e., the solder mask 113 has a plurality of bump opening 114 smaller the SMD pads 112 to define the soldering area of the SMD pads 112 as shown in FIG. 2. The chip 120 has an active surface 121 and a plurality of metal pillars 122 disposed on the active surface 121 where a plurality of solder 123 are disposed on the extruded ends 122A of the metal pillars 122. During reflowing processes, the solder 123 is melted to effectively join to the SMD pads 112 without melting the metal pillars 122 to provide mechanical support and to avoid bridging between adjacent metal pillars. The solder 123 does not solder to the peripheries of the SMD pads 112 nor to other metal traces due to the dimension restriction of the bump opening 114 of the solder mask 113. Moreover, the package body 150 is formed between the chip 120 and the substrate 110 to encapsulate the metal pillars 122. However, the metal pillars 122 have to be aligned one-by-one and jointed to the corresponding bump opening 114 of the solder mask 113 during flip-chip bonding the chip 120 to the substrate 110 to ensure good soldering between metal pillars 112 and the SMD pads 112. However, the SMD pads 114 are formed by the processes of printed circuit boards (PCB) where the manufacture accuracy is quite large and is different from the fabrication accuracy of IC processes leading to shifting issues. Moreover, the substrate 110 and the chip 120 will encounter thermal mismatching issues due to different material properties of CTE. Therefore, the metal pillars 122 can not accurately align to the bump opening 114 during MPS-C2 jointing processes causing empty soldering or false soldering leading to product reliability issues.

### SUMMARY OF THE INVENTION

The main purpose of the present invention is to provide a semiconductor package with MPS-C2 configuration to make solder on the metal pillars effectively join to the leads of a substrate where the soldering area of the leads can be controlled to eliminate the issues of excessive solder ability due to solder expansion on conventional NSMD connecting pads, peeling issues due to poor adhesion of NSMD connecting pads, and empty soldering or false soldering issues on conventional SMD connecting pads due to poor manufacture accuracy of PCB processes in the conventional MPS-C2 technology.

The second purpose of the present invention is to provide a semiconductor package with MPS-C2 configuration to keep a constant flip chip gap to ensure good horizontal leveling between a chip and a substrate to achieve better reliability of MPS-C2 products.

The third purpose of the present invention is to provide a semiconductor package with MPS-C2 configuration to eliminate the conventional solder mask restrictions to provide better layout flexibility for metal pillars with fine pitch bumping applications.

According to the present invention, a semiconductor package with MPS-C2 configuration is revealed primarily comprising a substrate and a chip. A plurality of leads are disposed on a top surface of the substrate and a solder mask covers the top surface. The solder mask has a slot partially exposing the leads, wherein a central part of the solder mask located inside the slot covers a plurality of internal segments of the leads and a peripheral part of the solder mask located outside the slot covers a plurality of external segments of the leads. The chip has an active surface and a plurality of metal pillars disposed on the active surface, wherein a plurality of solders are disposed on a plurality of extruded ends of the metal pillars for soldering to the leads. A patterned plating layer is partially formed on the exposed portions of the leads located inside the slot to constitute a plurality of plating-defined fingers so that the solders on the soldering area of the leads will not exceed the patterned plating layer.

A semiconductor package with MPS-C2 configuration according to the present invention has the following advantages and functions:
1. Through a specific combination of the solder mask and the patterned plating layer as a technical mean, since the solder mask has a slot partially exposing the leads and a patterned plating layer is partially formed on the exposed portions of the leads located inside the slot to constitute a plurality of plating-defined fingers, therefore, the solder on the metal pillars can be jointed to the leads of the substrate with the soldering area of the leads under well controlled without the issue of excessive solder ability due to solder expansion on the NSMD connecting pads, peeling issues due to poor adhesion of NSMD connecting pads, and empty soldering or false soldering issues on the SMD connecting pads due to poor manufacture accuracy of PCB processes in the conventional MPS-C2 technology.
2. Through a specific combination of the solder mask and the patterned plating layer as a technical mean, since a plurality of plating-defined fingers are defined by the patterned plating layer in slot, the solder is constrained on the soldering area of the leads without exceeding the patterned plating layer so that a flip chip gap can be kept to ensure good horizontal leveling between a chip and a substrate to achieve better reliability of MPS-C2 products.
3. Through a specific combination of the solder mask and the patterned plating layer as a technical mean, since the dimensions and shapes of the leads are not defined by the solder mask, the conventional solder mask restrictions can be eliminated to provide better layout flexibility for metal pillars with fine pitch bumping applications.

### DESCRIPTION OF THE DRAWINGS

FIG. 1 is a cross-sectional view of a conventional MPS-C2 package.

FIG. 2 is a top view of the substrate of a conventional MPS-C2 package.

FIG. 3 is a cross-sectional view of a semiconductor package with MPS-C2 configuration according to the first embodiment of the present invention.

FIG. 4 is a top view of the substrate of the semiconductor package according to the first embodiment of the present invention.

FIG. 5 is a partially enlarged view of the semiconductor package during flip-chip bonding according to the first embodiment of the present invention.

FIG. 6 is a top view of a plating-defined finger of the semiconductor package according to the first embodiment of the present invention.

FIG. 7 is a cross-sectional view of another semiconductor package with MPS-C2 configuration according to the second embodiment of the present invention.

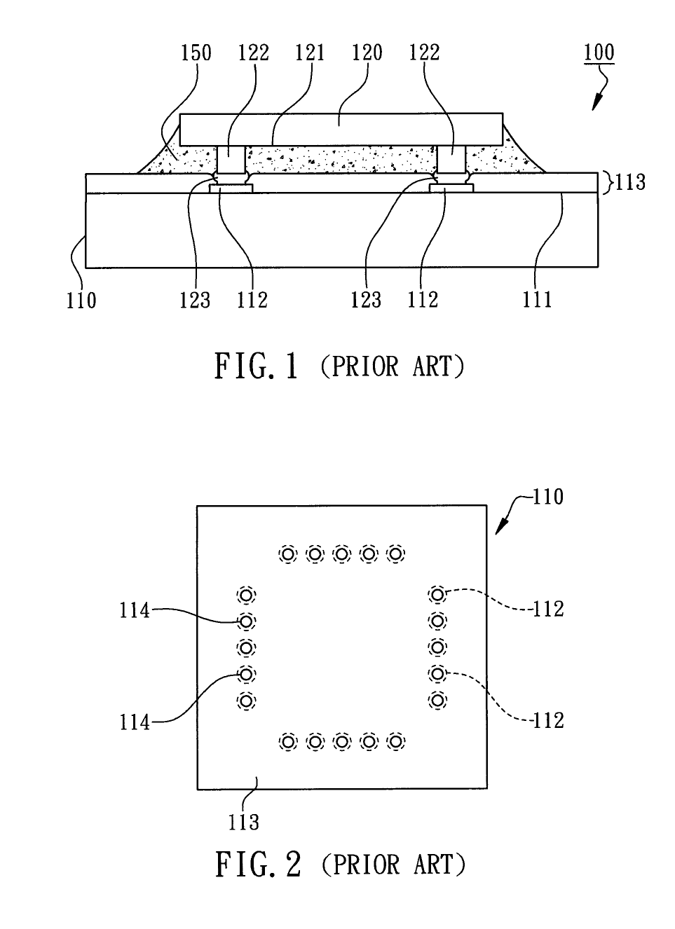

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

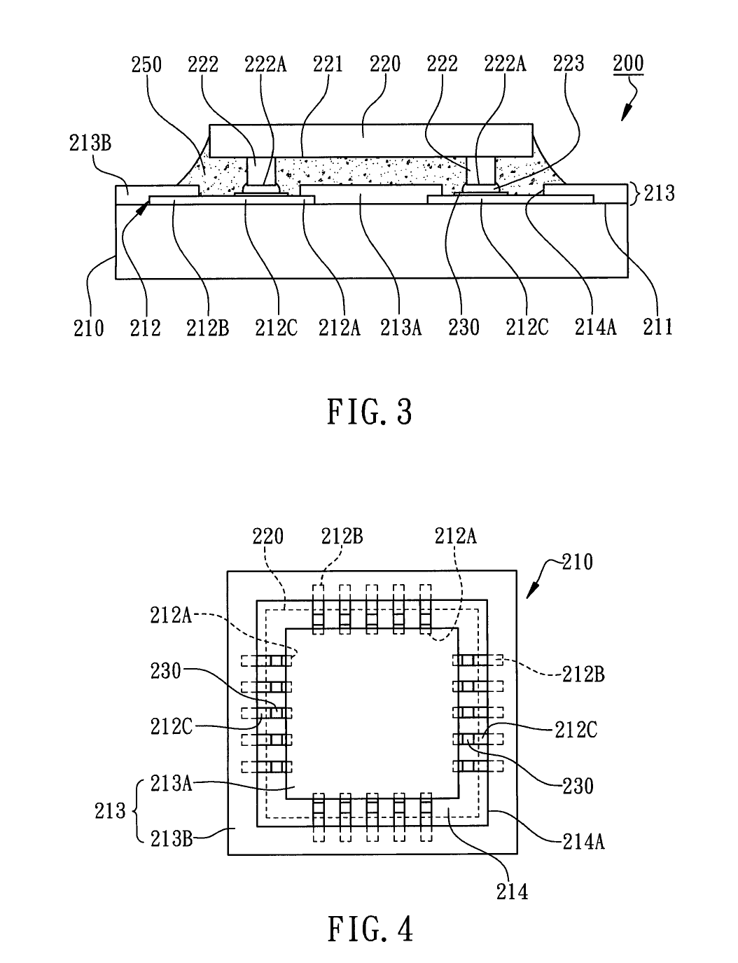

According to the first embodiment of the present invention, a semiconductor package with MPS-C2 configuration is illustrated in FIG. 3 for a cross-sectional view and in FIG. 4 for a top view of the substrate. The semiconductor package 200 with MPS-C2 configuration primarily comprises a substrate 210 and a chip 220. In a detail description, a plurality of leads 212 are disposed on a top surface 211 of the substrate 210 and the top surface 211 is covered by a solder mask 213, wherein the leads 212 are made of conductive materials for electrical transmission, such as copper. The leads 212 have a width greater than the one of metal traces and almost equal to or greater that the one of metal pillars 222 as shown in FIG. 6. Usually the substrate 210 is a printed circuit board and the leads 212 are parts of the internal circuitry of the substrate 210. The solder mask 213 is an insulating coating to protect the internal circuitry. Moreover, the solder mask 213 has a slot 214 as shown in FIG. 4 to partially expose the leads 212. As shown in FIG. 3 and FIG. 4, the solder mask 213 is divided by the slot 214 to include a central part 213A located inside the slot 214 and a peripheral part 213B located outside the slot 214 where the central part 213A covers a plurality of internal segments 212A of the leads 212 and the peripheral part 213B covers a plurality of external segments 212B of the leads 212 so that both ends of the leads 212 are covered by the solder mask 213 to achieve better adhesion of the leads 212 on the substrate 210. To be more specific, the covered external segments 212B are longer than the covered internal segments 212A to be a fan-out design for connecting external terminals or plated through holes (not shown in figures). In a preferred embodiment, the slot 214 can be a rectangular ring to enhance under-filling processes. The width of the slot 214 ranges from 200 um to 300 um. The length of the exposed portions 212C of the leads 212 located inside the slot 214 can be equal to the width of the slot 214 ranging from 200 um to 300 um which is much larger than the length of the soldering area.

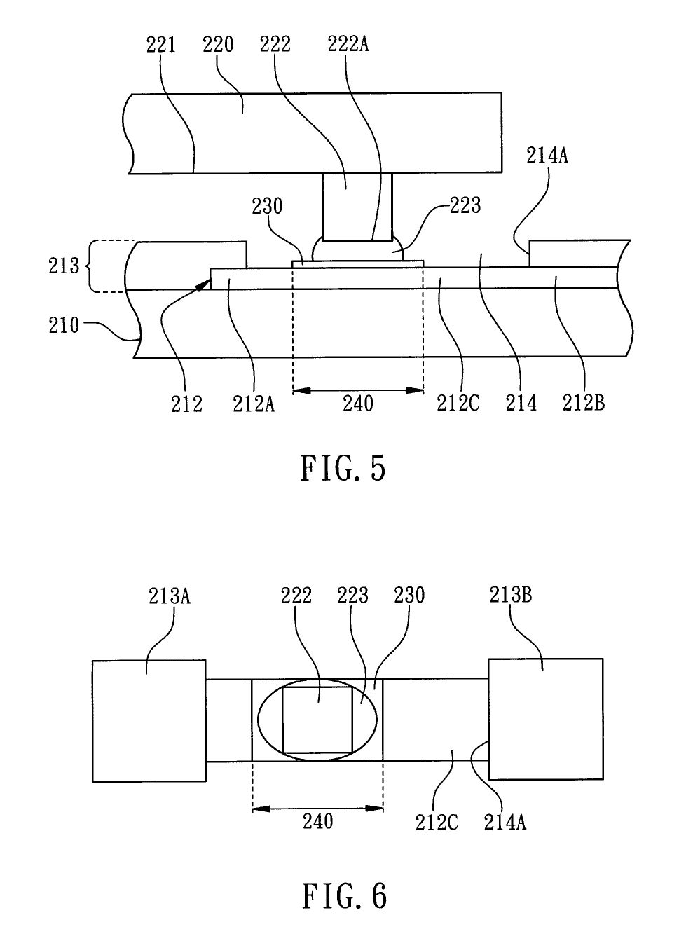

Referred to FIG. 3 along with the partially enlarged view in FIG. 5, the chip 220 is a semiconductor-based IC component such as memory, logic, and ASIC. The chip 220 has an active surface 221 and a plurality of metal pillars 222 disposed on the active surface 221 where the active surface 221 is the IC fabrication surface. The metal pillars 222 are the external terminals of the IC. A plurality of solders 223 are disposed on the extruded ends 222A of the metal pillars 222 to join the metal pillars 222 of the chip 220 to the leads 212 of the substrate 210 by reflowing processes. In the present embodiment, the material of the metal pillars 222 can be chosen from Cu with good electrical conductivity and without shape changing during reflowing processes. Furthermore, after reflowing processes, the chip 220 has a footprint vertically projected on the substrate 210.

As shown in FIG. 4, specially referred to the enlarged views of the leads in FIG. 5 and FIG. 6, a patterned plating layer 230 is partially formed at the portions 212C of the leads 212 located inside the slot 214 to define a plurality of plating-defined fingers 240 as shown in FIG. 5 and FIG. 6 to constrain the soldering area of the solders 223 on the leads 212 without exceeding the patterned plating layer 230. The material of the patterned plating layer 230 can be Au (gold) or other soldering enhanced materials. In the present embodiment, the extended length of the patterned plating layer 230 along one of the leads 212 ranges from 40 um to 60 um which is much smaller than the length of the exposed portions 212C of the leads 212 located inside the slot 214 ranging from 200 um to 300 um. As shown in FIG. 5 and FIG. 6, the above described plating-defined fingers 240 are defined where the patterned plating layer 230 is partially formed on the portions 212C of the leads 212 located inside the slot 214. As shown in FIG. 4, FIG. 5, and FIG. 6, the patterned plating layer 230 can be designed without direct contact to the solder mask 213 and an annular outside of the slot 214 is located outside the footprint of the chip 220 as shown in FIG. 4 so that it is obvious that the soldering areas of the leads 212 are not defined by the solder mask 213. Furthermore, as shown in FIG. 4 and FIG. 5, the patterned plating layer 230 is completely formed inside the footprint of the chip 220.

Moreover, as shown in FIG. 3, the semiconductor package with MPS-C2 configuration 200 further comprises a semiconductor package body 250 at least formed between the chip 220 and the substrate 210 to encapsulate the metal pillars 222. In a preferred embodiment, the package body 250 can be an underfill material to protect the metal pillars disposed on the active surface 221 of the chip 220 and to smoothly and completely encapsulate the exposed portions 212C of the leads 212 to prevent the portions 212C expose and oxidize in the air.

In the present invention, through a specific combination of the solder mask and the patterned plating layer as a technical mean, the plating-defined fingers 240 are formed by the patterned plating layer 230 partially formed on the portions 212C of the leads 212 located inside the slot 214 where the slot 214 of the solder mask 213 is shaped like a rectangular ring to expose all the leads 212 but not one by one. Therefore, when the chip 220 is jointed to the substrate 210, the soldering area of the solders 223 on the leads 212 can be well controlled within the plating-defined fingers 240 through the patterned plating layer 230. Since the solders 223 will not over expand during reflowing processes, so the issue of excessive solder ability due to solder expansion on conventional NSMD connecting pads, peeling issues due to poor adhesion of NSMD connecting pads, and empty soldering or false soldering issues on conventional SMD connecting pads due to poor manufacture accuracy of PCB processes in the conventional MPS-C2 technology can be avoid. Moreover, through the metal pillars 222 and the controlled soldering area of the solders 223, a constant flip-chip bonding gap can be kept to ensure good horizontal leveling between a chip and a substrate to achieve better reliability of MPS-C2 products. Furthermore, since the dimensions and shapes of the leads 212 in the present invention are not defined by the solder mask 213, the conventional solder mask restrictions can be eliminated to provide better layout flexibility for metal pillars with fine pitch bumping applications where the chip 220 can be closely bonded to the substrate 210

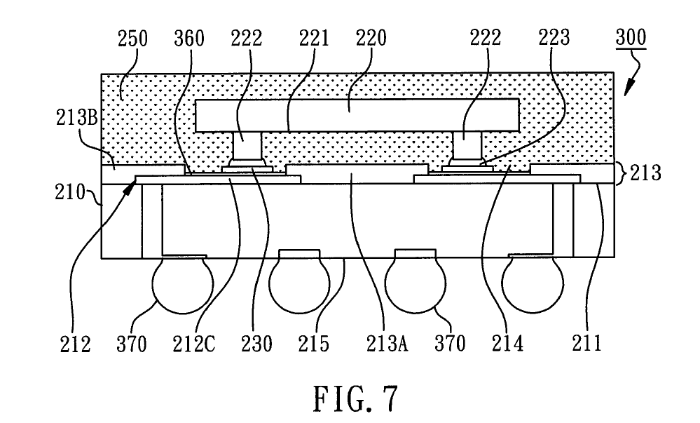

According to the second embodiment of the present invention, another semiconductor package with MPS-C2 configuration is illustrated in FIG. 7 for a cross-sectional view. The semiconductor package 300 with MPS-C2 configuration primarily comprises a substrate 210 and a chip 220 where the major components are almost the same as described in the first embodiment so that the same numbers are adapted without further description.

In the present embodiment, a barrier plating layer 360 can be completely disposed over the exposed portions 212C of the leads 212 located inside the slot 214 where the patterned plating layer is disposed on top of the barrier plating layer 360. The barrier plating layer 360 has an anti-wetting property for the solder 223 more than the leads 212 and the patterned plating layer 230. The material of the barrier plating layer may be Ni (nickel) so that the portions 212C of the leads 212 do not expose and oxidize in the air. Furthermore, the semiconductor package 300 further comprises a semiconductor package body 350 at least formed between the chip 220 and the substrate 210 to encapsulate the metal pillars 222. Preferably, the package body 350 can completely encapsulate the chip 220. To be more specific, the package body 350 can be an epoxy molding compound (EMC) including epoxy resin or polymer containing silica filler. The slot 214 can enhance the mold-flow filling of package body 350 into the gap between the chip 220 and the substrate 210. Furthermore, the semiconductor package 300 further comprises a plurality of external terminals 370 such as solder balls disposed on a bottom surface 215 of the substrate 210 for external electrical connections where the substrate 210 has plated through holes/vias with the corresponding traces to electrically connect the leads 212 on the top surface 211 to the ball pads on the bottom surface 215 so that the electrical terminals 370 are the external electrical connections for the chip 220. The package body 350 may completely encapsulate the chip 220, the metal pillars 222, and the solders 223 to provide thoroughly protection as well as to enhance the interface adhesion in the package, especially, the joint strength between the solders 223 of the metal pillars 222 and the patterned plating layer 230. Therefore, the reliability of MPS-C2 products can greatly be increased.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A semiconductor package with MPS-C2 (metal post solder-chip connections) configuration, comprising:
a substrate having a plurality of leads disposed on a top surface of the substrate and a solder mask covering the top surface, wherein the solder mask has a slot partially exposing the leads, wherein a central part of the solder mask located inside the slot covers a plurality of internal segments of the leads and a peripheral part of the solder mask located outside the slot covers a plurality of external segments of the leads; and
a chip having an active surface and a plurality of metal pillars disposed on the active surface, wherein a plurality of solders are disposed on a plurality of extruded ends of the metal pillars for soldering to the leads;
wherein the substrate further has a patterned plating layer partially formed on the exposed portions of the leads located inside the slot to constitute a plurality of plating-defined fingers to constrain the soldering area of the solders on the leads without exceeding the patterned plating layer.

2. The semiconductor package as claimed in claim 1, wherein the patterned plating layer does not direct contact with the solder mask and an annular outside of the slot is located outside a footprint of the chip.

3. The semiconductor package as claimed in claim 2, wherein the patterned plating layer is completely formed within the footprint of the chip.

4. The semiconductor package as claimed in claim 1, wherein the material of the patterned plating layer is gold.

5. The semiconductor package as claimed in claim 1, wherein the substrate further has a barrier plating layer completely formed over the portion of the leads located inside the slot and the patterned plating layer is partially formed on the barrier plating layer.

6. The semiconductor package as claimed in claim 5, wherein the material of the barrier plating layer is Ni.

7. The semiconductor package as claimed in claim 1, wherein the slot is a rectangular ring.

8. The semiconductor package as claimed in claim 1, wherein the width of the slot ranges from 200 um to 300 um and the extended length of the patterned plating layer along one of the leads ranges from 40 um to 60 um.

9. The semiconductor package as claimed in claim 1, further comprising a semiconductor package body at least formed between the chip and the substrate to encapsulate the metal pillars.

10. The semiconductor package as claimed in claim 9, wherein the package body is an underfill material.

11. The semiconductor package as claimed in claim 9, wherein the package body is an epoxy molding compound.

12. The semiconductor package as claimed in claim 11, wherein the package body further completely encapsulates the chip.

13. The semiconductor package as claimed in claim 1, further comprising a plurality of external terminals disposed on a bottom surface of the substrate.
